(19) United States
(12) Patent Application Publication
(10) Pub. No.: US 2021/0325437 A1
(43) Pub. Date: Oct. 21, 2021

(54) Cached Peak Graphical Display for Spectrum Analyzers

(71) Applicant: Research Electronics International, LLC, Cookeville, TN (US)

(72) Inventor: Thomas H. Jones, Cookeville, TN (US)

(21) Appl. No.: 16/852,535

(22) Filed: Apr. 19, 2020

(51) Int. Cl. G01R 29/08; G01R 13/02

(52) U.S. Cl. CPC G01R 29/0892; G01R 13/02

(57) ABSTRACT

A spectrum analyzing device and method include sweeping a first frequency range at least once at a first resolution and performing a Fast Fourier Transform (FFT) on data from the sweeping of the first frequency range to produce first peak hold trace data. A second frequency range is swept at least once at a second resolution and an FFT applied to produce second peak hold trace data based on the sweeping of the second frequency range. The resolution for the sweeps is selected based on a bandwidth of the frequency range to be swept. A composite graphical display is produced based upon the first and second peak hold trace data. By caching the peak hold trace data, the spectrum analyzer preserves detected signal information when zooming from a coarser to a finer frequency resolution while minimizing the processing requirements of the spectrum analysis.

### CROSS-REFERENCES TO RELATED APPLICATIONS

Not Applicable.

### STATEMENT REGARDING FEDERALLY SPONSORED RESEARCH OR DEVELOPMENT

Not Applicable.

### REFERENCE TO SEQUENCE LISTING OR COMPUTER PROGRAM LISTING APPENDIX

Not Applicable.

### BACKGROUND

Frequency spectrum analyzers are relatively common products with a broad range of commercial applications. Examples of such applications include, but are not limited to, commercial radio frequency (RF) technologies such as AM, Cellular, PCS, DCS, 2G, 3G, 4G, LTE, CDMA, cdmaOne, CDMA 2000, W-CDMA/CDMA, lx EV-DO, DECT phones, GSM, GPRS, EDGE, FM, UMTS, HSDPA, W-CDMA, TDMA, AMPS as well as 802.11, Bluetooth, Broadcast, Emergency, Fire, GPS, HDTV, IBOC, In-Building, Microwave, NPSPAC, Paging, Police, Private radio, Project 25, Public, RADAR, Safety, Telematics, TETRA, Trunking, UMTS, Utilities, WiMAX, Wi-Fi, WLAN and WLL. Spectrum analyzers are used to perform a wide variety of tasks that can occur in connection with these commercial RF applications such as installation, maintenance, troubleshooting, antenna alignment, RF measurements for radio and TV broadcasting, mobile phone base station radiation power density measurements, magnetic interference or leakage from motors and/or miscellaneous machinery, testing of wiring for RF energy, electromagnetic field strength measurement for various EMC limits, and cellular/cordless phone radiation levels.

Universities, community colleges, vocational schools, and high schools also use spectrum analyzers for educational labs and research. There is a similar demand from small start-up companies, hobbyists and individual inventors for a low cost spectrum analyzer that they can use in developing and exploring new product innovations. Spectrum analyzers may also be used in the home to address personal living environment RF safety concerns.

Additional examples of the commercial use of spectrum analyzers during everyday tasks include searching for unknown RF transmissions, FCC compliance, monitoring blasting sites, identifying RF interference impacting communications systems, security surveys for corporate board rooms, VIP protection, protection of intellectual property, detection and location of magnetic fields, and detection of signal interference and undesired RF emissions from medical equipment.

Unknown RF transmissions may represent the output of surveillance devices. Many such surveillance devices utilize burst transmissions whereby the surveillance device periodically performs a brief transmission while mainly remaining silent in order to avoid detection by a device such as a spectrum analyzer.

Therefore, what is needed is an improved system and method for detecting transient RF transmissions.

### BRIEF SUMMARY

The present invention is generally directed toward improvements in the detection of transient RF transmissions. More particularly, an embodiment of the present invention is directed toward a spectrum analyzer comprising processing circuitry configured to sweep a first frequency range at least once at a first resolution; produce first peak hold trace data based on the at least one sweep of the first frequency range; sweep a second frequency range at least once at a second resolution; produce second peak hold trace data based on the at least one sweep of the second frequency range and produce a composite graphical display based upon the first and second peak hold trace data. The composite graphical display may only be produced if second resolution may be finer than the first resolution such that the likelihood of detecting a transient RF transmission is not decreased while the processing demands placed on the spectrum analyzer are reduced.

A number of additional features may be incorporated into a spectrum analyzer constructed in accordance with an embodiments of the present invention. For example, the spectrum analyzer's processing circuitry may be further configured to identify peaks above a predetermined threshold in the first peak hold trace data; store the identified peaks in the first peak hold trace data in a memory and automatically add the identified peaks to a graphical display of the second peak hold trace data. In yet other variations, the spectrum analyzer's processing circuitry may be configured to select a trace resolution based on a bandwidth of the frequency range to be swept, perform a Fast Fourier Transform (FFT) on data from the at least one sweep of the first frequency range to produce the first peak hold trace data, not store peak hold trace data for a peak hold trace that meets a specified criteria to minimize storage requirements, use a look up table to determine at least one of a resolution and a FFT size to use for a specified bandwidth and/or allow a user to selectively clear stored peak hold traces.

Another embodiment of the present invention is directed toward a method of producing a graphical display. In accordance with the method, a first frequency range is swept at least once at a first resolution. First peak hold trace data is produced based on the at least one sweep of the first frequency range. A second frequency range is swept at least once at a second resolution. Second peak hold trace data is produced based on the at least one sweep of the second frequency range. A composite graphical display is produced based upon the first and second peak hold trace data. In order to reduce processing overhead, in certain embodiments a composite graphical display based upon the first and second peak hold trace data may only be produced if the second resolution is finer than the first resolution.

A number of optional steps can be added to methods of producing a graphical display in accordance with embodiments of the present invention. For example, the method may further include identifying peaks above a predetermined threshold in the first peak hold trace data; storing the identified peaks in the first peak hold trace data in a memory and automatically adding the identified peaks to a graphical display of the second peak hold trace data. In other variations, the method may include selecting a trace resolution based on a bandwidth of the frequency range to be swept, performing a Fast Fourier Transform (FFT) on data from the at least one sweep of the first frequency range to produce the first peak hold trace data, not storing store peak hold trace data for a peak hold trace that meets a specified criteria, using a look up table to determine at least one of a resolution and a FFT size to use for a specified bandwidth and/or allowing a user to selectively clear stored peak hold traces.

Yet another embodiment is directed toward a method of displaying collected spectrum analyzer data. In accordance with the method, peaks are identified in a first peak hold trace graphical display for a first frequency span having a first resolution. The identified peaks in the first peak hold trace graphical display are stored in a stored peak memory. The stored peaks are automatically added to a second peak hold trace graphical display having a second resolution. The method may be performed if first resolution is coarser than the second resolution. Further, a user may be allowed to select stored identified peaks for display on a current peak trace display.

### BRIEF DESCRIPTION OF THE SEVERAL VIEWS OF THE DRAWINGS

FIG. 1 is an illustration of an exemplary peak hold trace display for a spectrum analyzer in accordance with an embodiment;

FIG. 2 is an illustration of another exemplary peak hold trace display in accordance with an embodiment;

FIG. 3 is an illustration of another exemplary peak hold trace display in accordance with an embodiment;

FIG. 4 is an illustration of an exemplary peak hold trace display with added cached peak hold traces in accordance with an embodiment;

FIG. 5 is a block diagram of a spectrum analyzer constructed in accordance with an embodiment;

FIG. 6 is an illustration of an exemplary data flow in accordance with some embodiments;

FIG. 7 is a flow chart of a cached peak processing method for producing a graphical display in accordance with some embodiments;

FIG. 8 is a flow chart of a cached peak processing method for producing a graphical display in accordance with some embodiments; and

FIG. 9 is a flow chart of a cached peak processing method for producing a graphical display in accordance with some embodiments.

The present invention will now be described with reference to the accompanying drawings. In the drawings, like reference numbers indicate identical or functionally similar elements.

### DETAILED DESCRIPTION

Spectrum analyzer products may be optimized for the counter-surveillance market and associated use-cases. One key use-case is the gathering and display of a “peak trace.” The peak trace retains and displays to the user the maximum radio frequency (RF) power observed at various RF frequencies by the spectrum analyzer during the scanning period. The user may use the peak trace information to guide their search for illicit surveillance devices which may be emitting RF energy. The peak trace functionality is especially critical to the user when searching for sporadic or burst RF transmitter devices that produce a temporary signal before going silent.

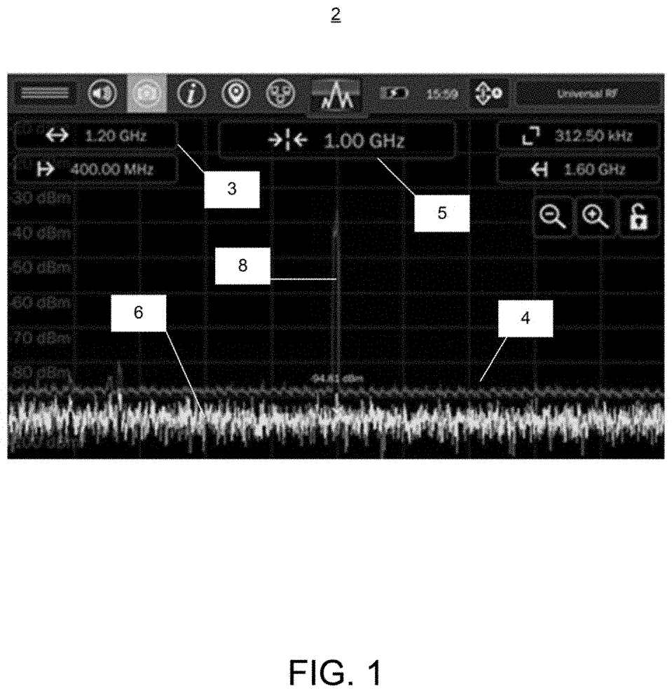

Referring now to FIG. 1, an illustration of an exemplary peak hold trace display 2 for a set of spectrum analyzer data is shown. In the example shown, the peak trace display 2 displays a peak hold trace 4 and a current RF trace 6, i.e., the current state of the RF environment. The bandwidth 3 and center frequency 5 of the displayed frequency range are displayed near the top of the display 2. The peak trace 4 of FIG. 1 clearly shows a relatively large peak 8 of detected RF energy close to the center frequency 5 of 1.00 GHz. Given that the current trace 6 currently shows only low-level, noise-floor energy, the user may infer that RF energy was previously present at this frequency, but the transmission source is not currently active. Thus, the use of a peak hold functionality may be an important tool when attempting to detect transient RF transmissions.

As described herein, various embodiments of the present invention are directed toward a display for a Fast Fourier Transform (FFT) based spectrum analyzer. In an FFT based spectrum analyzer, the engineers and designers are faced with various performance tradeoffs such as resolution, sweep speed, and data throughput. One key optimization variable is the resolution of the spectrum data being processed which is impacted by the number of points enabled by the FFT, which in-turn may or may not be dynamically configurable.

In an implementation where the FFT size is dynamically configurable, the spectrum analyzer may select fewer FFT points, which provides a coarser frequency resolution, when sweeping a wide overall bandwidth, enabling faster overall sweep speeds. Conversely, the spectrum analyzer may select more FFT points, which provides a finer frequency resolution, when sweeping a smaller overall bandwidth. In doing so, the spectrum analyzer is making performance tradeoffs optimized for the counter-surveillance market, although other spectrum analyzer use-cases and target markets may make similar design decisions.

One side effect of dynamically changing the resolution is that peak traces collected at one frequency resolution are not necessarily mathematically related or aligned to peak traces collected at another frequency resolution. As such, when a user zooms in to a smaller frequency bandwidth, the spectrum analyzer may be forced to clear the current peak trace and create a new peak trace when the analyzer selects a new resolution. Furthermore, the ability to manage and update the peak trace as the device transitions between different FFT sizes (and hence resolutions) may also be impacted by available central processing unit (CPU) power and/or available random access memory (RAM) for storing and processing peak trace data. An implementation may simply avoid all these constraints and force the current peak trace to clear and reset itself as the underlying spectrum trace resolution is dynamically changed. Such an implementation is relatively both CPU and RAM efficient. However, such an implementation will cause the user of the device to lose valuable information and RF signal context as they search for illicit surveillance devices and their associated RF signals.

Embodiments of the present disclosure address this loss of context and information by creating a system and method for caching, updating, and displaying cached peak trace data previously acquired at coarser resolutions even when the user has zoomed the display in to smaller frequency bandwidths with finer frequency resolutions.

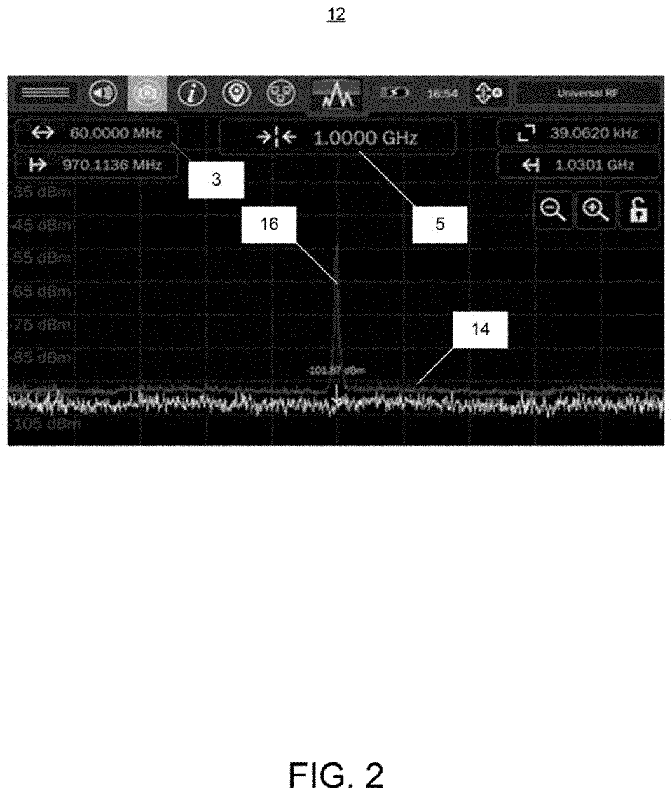

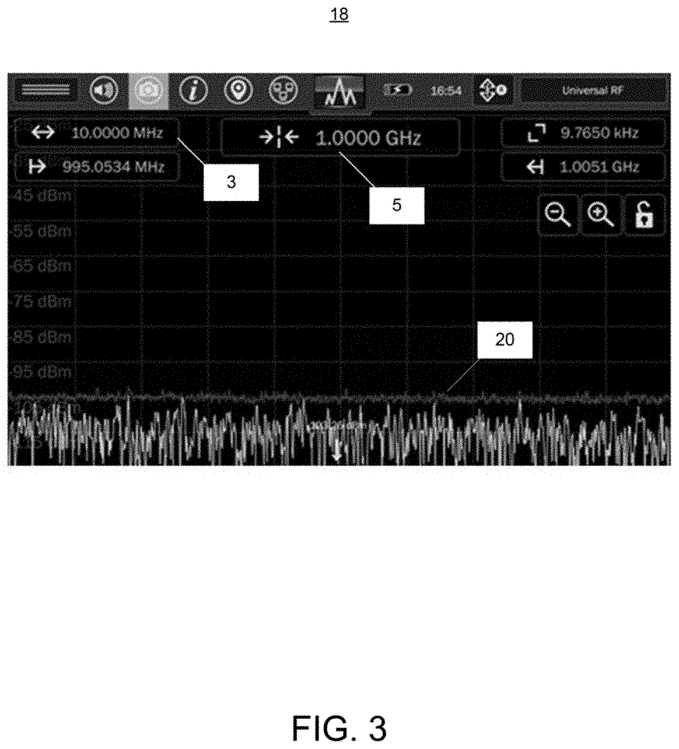

FIGS. 2 and 3 are illustrations of exemplary peak hold trace displays for a spectrum analyzer wherein the spectrum analyzer clears the current peak trace and resets itself as the spectrum trace resolution is dynamically changed. In FIG. 2, a graphical display 12 displaying a peak hold trace 14 derived from FFT's of selected data points from a frequency spectrum dataset is shown. The display 12 of FIG. 2 is 60 MHz in bandwidth centered around a frequency of 1 GHz. A relatively high peak 16 in RF energy that has been detected is clearly displayed in the center of the displayed bandwidth of displayed FFT data.

In contrast to the display of FIG. 2, the display 18 of FIG. 3 displays only 10 MHz in bandwidth centered around a frequency of 1 GHz. In changing from the display of FIG. 2 to the display of FIG. 3, as a result of the finer resolution displayed on the display of FIG. 3, the spectrum analyzer has cleared the data points used for the prior display of FIG. 2 and replaced them with a new set of data points from the latest scan to reset the FFT operation. As discussed above, this may be necessary to meet processing and memory constraints. However, as a result of resetting the data points of the FFT, the previously detected signal peak 16 has been lost and is not present in the displayed peak hold trace 20. This results in the peak 16 of FIG. 2 not appearing in the display of FIG. 3 even though the frequency range of the peak is included in the previously displayed frequency bandwidth.

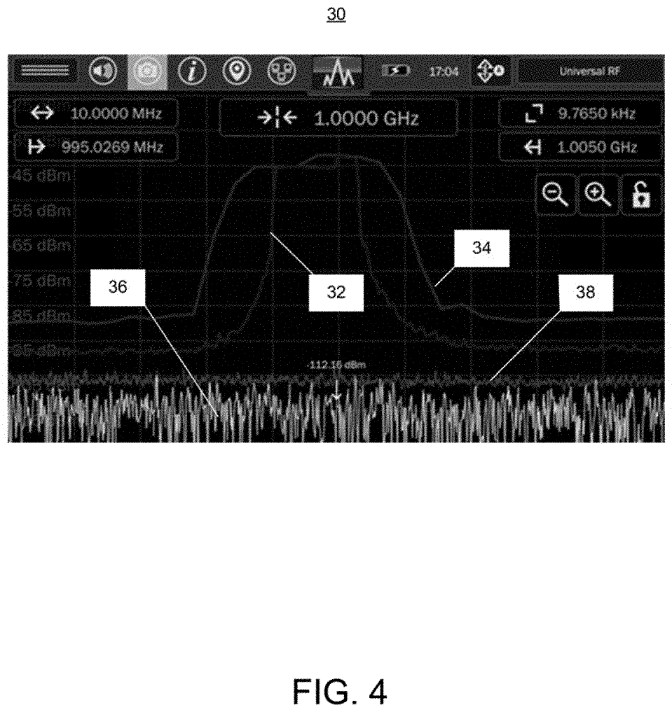

This loss of peak data can be remedied by storing any detected peaks in a cache and imposing them on later displays of the same frequency spectrum at different frequency resolutions. As shown in the graphical display 30 of FIG. 4, the user is now able to see the full signal context gathered by the spectrum analyzing device while the user was sweeping at various other coarser resolutions. In FIG. 4, we see the display of two cached peak traces 32 and 34 imposed on the graphical display 30 which indicate that a signal was previously present while the spectrum analyzing device was sweeping two different larger spans/bandwidths and associated resolutions. In the interim, the user has narrowed their sweep to a small span to inspect the signal in more detail, however the signal is currently not active, as indicated by the displayed current trace 36, and has not been active during the finer resolution sweeping as indicated by the current peak hold trace 38. With the display of the cached peak traces 32 and 34, the user may now be confident that they are sweeping the correct frequency where a signal was previously emitted. Contrast these results with the results shown in FIG. 3 where the user has lost previous peak trace data due to the change in trace data resolution.

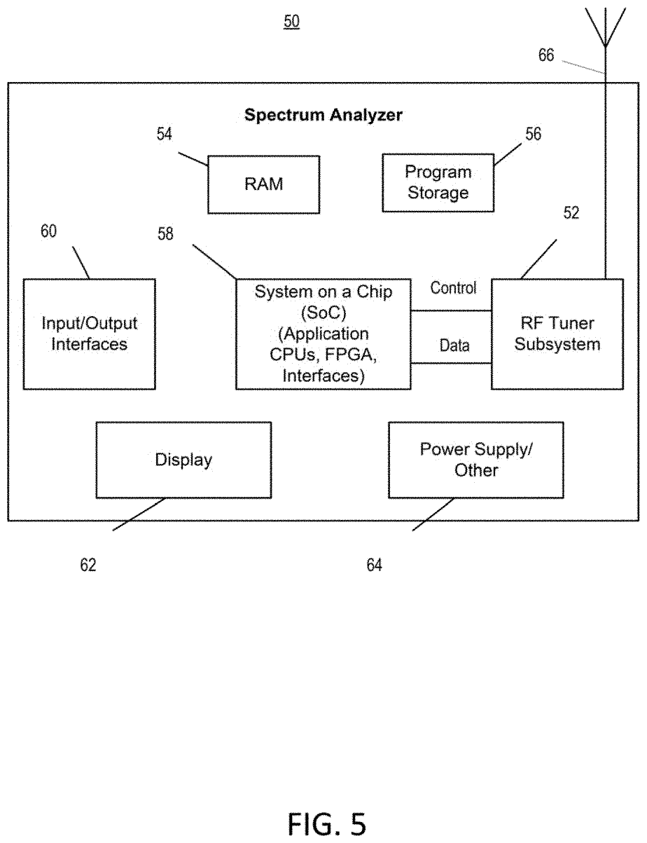

FIG. 5 is a block diagram of a RF spectrum analyzer system 50 constructed in accordance with some embodiments of the present invention. The RF spectrum analyzer system 50 includes processing circuitry for performing the required functions. One or more RF tuner subsystems 52 each capable of tuning to a single block/span of RF energy, for example a 20 MHz frequency span, and outputting digitized data representing properties of the tuned to block of RF energy are included in the RF spectrum analyzer system 50. The RF tuner subsystems 52 are coupled to an antenna 66 that is adapted to receive RF signals in the desired frequency ranges. In some embodiments, the antenna 66 is configured to be removable and replaceable with other antennas. This allows different antennas 66 that are specialized for each particular use case to be selectively coupled to the RF tuner subsystems 52.

The RF spectrum analyzer system 50 also includes a random access memory RAM 54. RAM 54 is used for storing the output of the FFT operations such as the current and cached peak hold trace data and any other data needed for the spectrum analysis as described herein.

The RF spectrum analyzer system 50 includes program storage 56, e.g. a field programmable gate array (FPGA), processing circuitry, etc., that stores digital logic used during the spectrum analysis. The digital logic is designed to control the coupled RF tuner(s) 52, process data received from the RF tuner(s) 52, perform FFT operations on the received data, and write RF spectrum trace data, i.e. the output of the FFT operations, to the coupled RAM 54 such that one or more of the operations may be coordinated to create a single sweep of trace data representing one or more blocks of RF energy.

The RF spectrum analyzer system 50 includes at least one application processor(s) 58, coupled to RAM 54 and the program storage 56 containing the digital logic. The application processor(s) 58 execute instructions to direct and control the coupled digital logic in the program storage 56 and associated RF tuner(s) 52 to create a RF spectrum trace representing a desired frequency span. In an embodiment, the application processor 58 may be a system on a chip (SoC) type processor that contains the application CPUs, FPGAs and interfaces for the spectrum analyzer 50 all on one chip.

The application processor(s) 58 execute instructions to direct and control the system to perform the required spectrum analysis functions. For example, the application processor(s) 58 may select the current trace resolution, i.e. control the FFT, based on predetermined and system optimized values, i.e. coarser resolutions for wide RF span sweeps, finer resolutions for narrow RF span sweeps. The application processor(s) 58 may also direct the digital logic in the program storage 56 to operate upon the RF tuner 52 to gather and create the desired current trace data for a particular RF span and output the data to RAM 54 that is coupled to the digital logic (FPGA) in program storage 56 and the application processor(s) 58.

The RF spectrum analyzer system 50 includes a display 62, such as a liquid crystal display (LCD) and/or touchscreen display, that is used to output a graphical display such as discussed herein with respect to FIGS. 1-4. The application processor(s) 58 may process the current trace data provided to the application processor(s) 58 and display a current trace based on the current resolution on the display 62. The current trace displays the results of the most recent sweep of the displayed frequency range.

The application processor(s) 58 may also create and maintain a current peak hold trace based on the current resolution in RAM 54 and display the current peak hold trace on display 62. The current peak hold trace displays the highest amount of RF energy detected within each frequency block within the frequency range being swept during a test period.

The application processor(s) 58 may also create and store to RAM 54 cached peak hold trace data based on the current resolution, if applicable. The cached peak hold trace data represents the highest amount of RF energy detected within each frequency block within a frequency range being swept during a prior test period at a particular resolution. The cached peak trace RAM 54 does not need to be coupled to directly to the digital logic, although it may be if desired.

The application processor(s) 58 may update cached peak trace(s) stored in RAM 54 for previously viewed RF spans based on newly acquired spectrum data. The application processor(s) 58 may also selectively display cached peak trace(s) stored in RAM for previously viewed RF spans.

Additionally, the application processor(s) 58 may also be configured to direct and control the spectrum analyzing user interface to perform functions such as (1) enable a user interface where the user may select a span of RF spectrum for display; (2) enable a user interface to display the current trace data; (3) enable a user interface to enable or disable the display of a current peak trace; (4) enable a user interface to enable or disable the display of a cached peak trace(s); (5) enable a user interface to direct the system to clear the current peak trace; and (6) enable a user interface to direct the system to clear the cached peak trace(s).

Additional conventional components of a spectrum analyzer such as input/output interfaces 60, a power supply 64, etc. may be included in the spectrum analyzer 50 as desired.

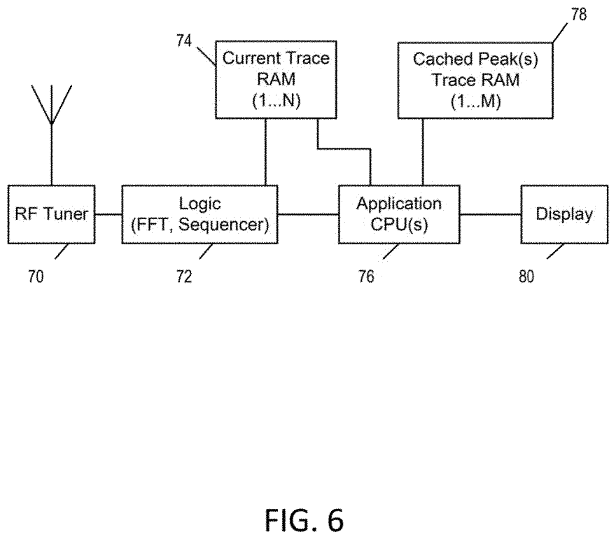

Referring now to FIG. 6, an exemplary data flow in accordance with some embodiments is shown. The underlying RF data is collected by the RF tuner 70 under the control of the digital logic 72, which may include FFT and sequencer logic as described herein. The application CPU(s) 76 control and exchange data with the program logic 72. The digital logic 72 may write the current trace data and current peak trace data to a current trace RAM 74. The current peak trace data is then read from the current trace RAM 74 by the application CPU(s) 76. For example, the application CPU(s) 76 may read the current trace data from the current trace RAM 74, identify peaks in the current trace data and store the identified peaks in a cached peak trace RAM 78. The application CPU(s) 76 may then combine the current trace data from the current trace RAM 74 with cached peak data stored cached peak trace RAM 78 to produce a composite graphical display 80 that displays both the current and cached peak data on a single display.

Embodiments of the methods and systems described herein may contain a lookup table of optimized trace resolutions given a desired RF sweep span (bandwidth). The lookup table can be optimized by the manufacturer of the spectrum analyzer for their target market requirements. The following is a non-limiting example of a lookup table for use in accordance with some embodiments.

| Bandwidth | FFT Size | Resulting Trace Resolution |
|---|---|---|
| 301 MHz- | 256 points, using 64 | 312500 Hz |
| 6 GHz | points | |
| 15 MHz- | 2048 points, using 512 | 39062.5 Hz |
| 300 MHz | points | |
| Below | 2048 points, using | Varies 9765 Hz or smaller |
| 15 MHz | variable | |

As shown in the table, each bandwidth is associated with a predetermined FFT size and resulting trace resolution. Once a user has selected a particular bandwidth, the processing circuitry of the spectrum analyzer can determine the FFT size to use to produce the trace data.

In accordance with some embodiments, the system may select only certain resolutions for cached peak behavior. For example, a system may only store and process cached peaks for a single resolution, such as 312500 Hz, or the system may store and process cached peaks for multiple resolutions such as 312500 Hz and 39062.5 Hz. The decision may be based on availability of CPU and RAM resources, among other product and market considerations.

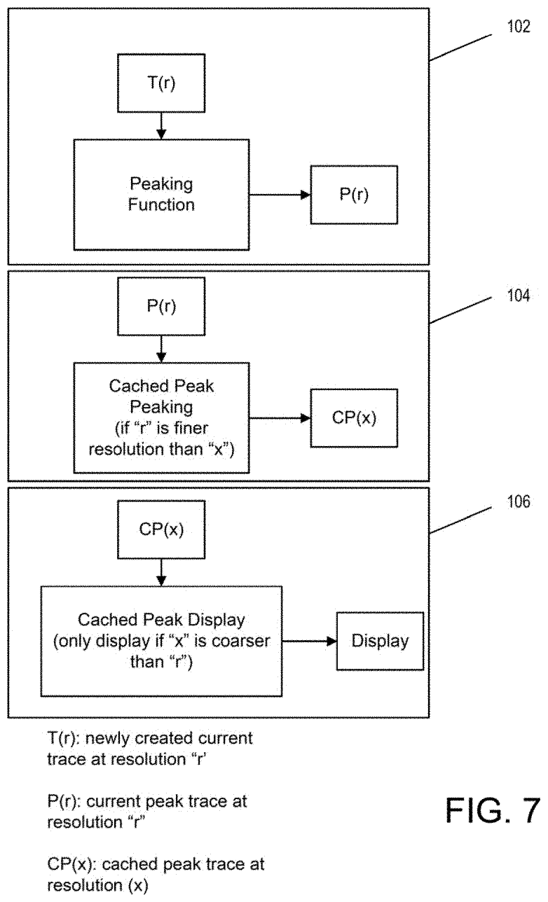

FIG. 7 is a flow chart of a cached peak processing method for producing a graphical display in accordance with some embodiments. The method can be divided into three main steps 102, 104 and 106 with each main step having sub steps. Let T(r) represent a newly created current trace created with a resolution r. In the first step 102 of the method of FIG. 7, a peaking function P is applied to the newly created current trace, T(r), at resolution r to identify peaks in the current trace. This peak information is then stored as a current peak trace P(r).

In the second step 104 of FIG. 7, if resolution r of the current peak trace, P(r) is a finer resolution than resolution x, which represents the resolution of a cached peak trace CP(x), the cached peak trace CP(x) is retrieved from a cached peak trace memory. Step 104 may be repeated if multiple cached peak traces are contained in the cached peak trace memory.

In the third step 106 of the method FIG. 7, if the resolution of a cached peak trace is coarser than the resolution of the current peak trace, a composite peak trace display is created based upon the current peak trace P(r) and the retrieved cached peak traces CP(x). Step 106 may be repeated for each cached peak trace contained in the cached peak trace memory.

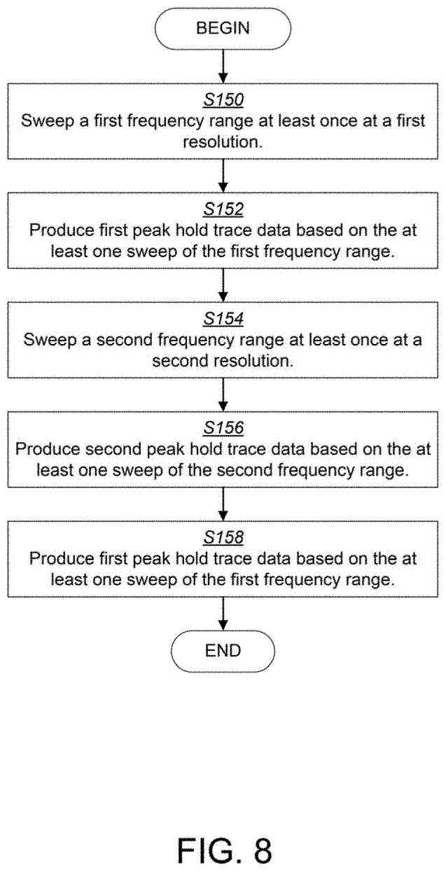

FIG. 8 is a flow chart of a method of producing a graphical display performed by a spectrum analyzer such as the spectrum analyzer shown in FIG. 5 in accordance with some embodiments. The method begins with the sweeping (Block S150) of a first frequency range at least once at a first resolution. In an embodiment, the trace resolution is based on a bandwidth of the frequency range to be swept. First peak hold trace data is then produced (Block S152) based on the at least one sweep of the first frequency range. A second frequency range is swept (Block S154) at least once at a second resolution. Second peak hold trace data is then produced (Block S156) based on the at least one sweep of the second frequency range. Finally, a composite graphical display is produced (Block S158) based upon the first and second peak hold trace data. The production of a composite graphical display based upon the first and second peak hold trace data may be restricted to situations where the second resolution is finer than the first resolution if desired.

The method of FIG. 8 can be adjusted for various use cases. In one such case, the method includes identifying peaks above a predetermined threshold in the first peak hold trace data; storing the identified peaks in the first peak hold trace data in a memory; and automatically adding the identified peaks to a graphical display of the second peak hold trace data. By identifying peaks, the need to store and process cached peak traces can be minimized. In another variation, the method includes selecting a trace resolution based on a bandwidth of the frequency range to be swept. Selecting a trace resolution based on a bandwidth of the frequency range to be swept allows the amount of required processing to be more precisely tailored to the displayed frequency range thereby reduces unnecessary processing overhead.

In a variation, the method includes performing a Fast Fourier Transform (FFT) on data from the at least one sweep of the first frequency range to produce the first peak hold trace data. Using an FFT to produce the peak hold trace data reduces the required processing power of the spectrum analyzer. The method may also include using a look up table to determine at least one of a resolution and an FFT size to use for a specified bandwidth. Using a look up table allows a spectrum analyzer to retrieve a desired resolution for the signal processing. Further, the look up table may be adjusted/tweaked/optimized by the manufacturer to meet certain processing and/or data requirements further minimizes the processing burdens imposed on the spectrum analyzer.

In a further variation, the method includes not storing store peak hold trace data for a peak hold trace that meets a specified criteria. By only storing peak hold traces that meet the specified criteria, such as containing a peak above a certain threshold, the unnecessary storing of unwanted peak trace data is reduced. A user may also be provided the option of selectively clearing stored peak hold traces to restart the process as desired.

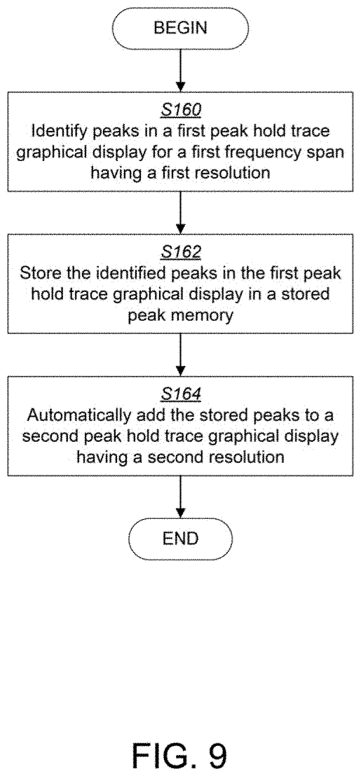

FIG. 9 is a flow chart of a method of producing a graphical display performed by a spectrum analyzer such as the spectrum analyzer shown in FIG. 5 in accordance with some embodiments. The method begins with the identifying (Block S160) of peaks in a first peak hold trace for a first frequency span having a first resolution. The identified peaks in the first peak hold trace are then stored (Block S162) in a peak memory. Finally, the stored peaks are automatically added (Block S164) to a second peak hold trace having a second resolution. The method of FIG. 9 may be limited to cases where the first resolution is coarser than the second resolution and varied with additional steps and features such as described above. For example, a user may be allowed to select which stored identified peaks to display on an output graphical peak hold trace display in accordance with the method.

Although there have been described particular embodiments of the present invention of a Cached Peak Graphical Display for Spectrum Analyzers, it is not intended that such references be construed as limitations upon the scope of this invention except as set forth in the following claims.

What is claimed is:

1. A spectrum analyzer comprising:
processing circuitry configured to:
sweep a first frequency range at least once at a first resolution;
produce first peak hold trace data based on the at least one sweep of the first frequency range;
sweep a second frequency range at least once at a second resolution;
produce second peak hold trace data based on the at least one sweep of the second frequency range; and
produce a composite graphical display based upon the first and second peak hold trace data.

2. The spectrum analyzer of claim 1 wherein the processing circuitry is configured to:
identify peaks above a predetermined threshold in the first peak hold trace data;
store the identified peaks in the first peak hold trace data in a memory; and
automatically add the identified peaks to a graphical display of the second peak hold trace data.

3. The spectrum analyzer of claim 1 wherein the processing circuitry is configured to select a trace resolution based on a bandwidth of the frequency range to be swept.

4. The spectrum analyzer of claim 1 wherein the processing circuitry is configured to perform a Fast Fourier Transform (FFT) on data from the at least one sweep of the first frequency range to produce the first peak hold trace data.

5. The spectrum analyzer of claim 1 wherein the processing circuitry is configured to not store peak hold trace data for a peak hold trace that meets a specified criteria.

6. The spectrum analyzer of claim 1 wherein the processing circuitry is configured to use a look up table to determine at least one of a resolution and an FFT size to use for a specified bandwidth.

7. The spectrum analyzer of claim 1 wherein the processing circuitry is configured to allow a user to selectively clear stored peak hold traces.

8. The spectrum analyzer of claim 1 wherein the processing circuitry is configured to produce a composite graphical display based upon the first and second peak hold trace data if the second resolution is finer than the first resolution.

9. A method of producing a graphical display comprising:
sweeping a first frequency range at least once at a first resolution;
producing first peak hold trace data based on the at least one sweep of the first frequency range;
sweeping a second frequency range at least once at a second resolution;
producing second peak hold trace data based on the at least one sweep of the second frequency range; and
producing a composite graphical display based upon the first and second peak hold trace data.

10. The method of claim 9 comprising:
identifying peaks above a predetermined threshold in the first peak hold trace data;
storing the identified peaks in the first peak hold trace data in a memory; and
automatically adding the identified peaks to a graphical display of the second peak hold trace data.

12. The method of claim 9 comprising selecting a trace resolution based on a bandwidth of the frequency range to be swept.

13. The method of claim 9 comprising performing a Fast Fourier Transform (FFT) on data from the at least one sweep of the first frequency range to produce the first peak hold trace data.

14. The method of claim 9 comprising not storing store peak hold trace data for a peak hold trace that meets a specified criteria.

15. The method of claim 9 comprising using a look up table to determine at least one of a resolution and an FFT size to use for a specified bandwidth.

16. The method of claim 9 comprising allowing a user to selectively clear stored peak hold traces.

17. The method of claim 9 wherein producing a composite graphical display based upon the first and second peak hold trace data comprises producing the composite graphical display if the second resolution is finer than the first resolution.

18. A method of displaying collected spectrum analyzer data, said method comprising:
identifying peaks in a first peak hold trace graphical display for a first frequency span having a first resolution;
storing the identified peaks in the first peak hold trace graphical display in a stored peak memory; and
automatically adding the stored peaks to a second peak hold trace graphical display having a second resolution.

19. The method of claim 18 wherein the first resolution is coarser than the second resolution.

20. The method of claim 18 comprising allowing a user to select stored identified peaks for display on a current peak trace display.
